(19) United States
(12) Patent Application Publication
(10) Pub. No.: US 2013/0033671 A1
(43) Pub. Date: Feb. 7, 2013

(54) LIQUID CRYSTAL POLYMER (LCP) SURFACE LAYER ADHESION ENHANCEMENT

(71) Applicants: Mark Schadt, Vestal, NY (US); Frank D. Egitto, Binghamton, NY (US); Luis J. Matienzo, Endicott, NY (US)

(72) Inventors: Mark Schadt, Vestal, NY (US); Frank D. Egitto, Binghamton, NY (US); Luis J. Matienzo, Endicott, NY (US)

(73) Assignee: ENDICOTT INTERCONNECT TECHNOLOGIES, INC., Endicott, NY (US)

(21) Appl. No.: 13/197,804

(22) Filed: Aug. 4, 2011

(51) Int. Cl. C09K 19/02; G01J 3/28; C23C 14/34; B05D 3/10; B05D 5/12; B05D 7/02; G01N 21/88; G01T 1/36

(52) U.S. Cl. 349/183; 356/237.3; 356/326; 378/82; 216/67; 427/536; 204/192.1; 205/205; 204/192.34

(57) ABSTRACT

A method of conditioning a liquid crystal polymer (LCP) substrate for enhanced surface adhesion accomplished by exposing an LCP substrate to oxygen plasma. The plasma will chemically alter and modify the LCP substrate surface to promote increased adhesion of metal and subsequent LCP layers during lamination. Lamination is accomplished while dwelling under the melt temperature of the LCP substrate itself. A further method is disclosed of detecting impurities modified or deposited onto the LCP surface during plasma treatment.

### FIELD OF THE INVENTION

The present invention relates to surface treatments and preparation of circuit boards and, more specifically, to a surface treatment of liquid crystal polymer (LCP) dielectric materials that increases the adhesion of metal and additional LCP layers, and a structure wherein LCP is utilized as a layer in a circuitized substrate.

### BACKGROUND OF THE INVENTION

The needs of the semiconductor marketplace continue to drive density into semiconductor packages. Traditionally, greater wiring densities have been achieved by reducing the dimensions of vias, lines, and spaces, increasing the number of wiring layers, and utilizing blind and buried vias. However, each of these approaches, for example, those related to drilling and plating of high aspect ratio vias, reduced conductance of narrow circuit lines, and increased cost of fabrication related to additional wiring layers, includes inherent limitations.

PCBs, chip carriers and related products used in many of today's technologies must include multiple circuits in a minimum volume or space. Typically, such products comprise a stack of layers of signal, ground and/or power planes separated from each other by at least one layer of electrically insulating dielectric material. The circuit lines or pads (e.g., those of the signal planes) are often in electrical contact with each other by plated holes passing through the dielectric layers. The plated holes are often referred to as vias if internally located, blind vias if extending a predetermined depth within the board from an external surface, or plated-thru-holes (PTHs) if extending substantially through the board's full thickness. The term thru-hole as used herein is meant to include all three types of such board openings.

Complexity of these products has increased significantly in recent years. PCBs for mainframe computers may have as many as seventy-two layers of circuitry or more, with the complete stack having a thickness of as much as about 0.800 inch (800 mils). These boards are typically designed with three or five mil wide signal lines and twelve mil diameter thru-holes. Increased circuit densification requirements seek to reduce signal lines to a width of two mils or less and thru-hole diameters to two mils or less. Many known commercial procedures, especially those of the nature described herein, are incapable of economically forming these dimensions now desired by the industry. Such processes typically comprise fabrication of separate innerlayer circuits (circuitized layers), which are formed by coating a photosensitive layer or film over the copper layer of a copper clad innerlayer base material. The photosensitive coating is imaged and developed and the exposed copper is etched to form conductor lines. After etching, the photosensitive film is stripped from the copper, leaving the circuit pattern on the surface of the innerlayer base material. This processing is also referred to as photolithographic processing in the PCB art and further description is not deemed necessary.

After the formation of the individual innerlayer circuits, a multilayer stack is formed by preparing a lay-up of core innerlayers, ground planes, power planes, etc., typically separated from each other by a dielectric prepreg comprising a layer of glass (typically fiberglass) cloth impregnated with a partially cured material, typically a B-stage epoxy resin. The top and bottom outer layers of the stack usually comprise copper clad, glass-filled epoxy planar substrates with the copper cladding comprising the exterior surfaces of the stack. The stack is laminated to form a monolithic structure using heat and pressure to fully cure the B-stage resin. The stack so formed typically has metal (usually copper) cladding on both of its exterior surfaces. Exterior circuit layers are formed in the copper cladding using procedures similar to the procedures used to form the innerlayer circuits. A photosensitive film is applied to the copper cladding. The coating is exposed to patterned activating radiation and developed. An etchant is then used to remove copper bared by the development of the photosensitive film. Finally, the remaining photosensitive film is removed to provide the exterior circuit layers.

The aforementioned thru-holes (also often referred to as interconnects) are used in many such substrates to electrically connect individual circuit layers within the structure to each other and to the outer surfaces. The thru-holes typically pass through all or a portion of the stack. Thru-holes are generally formed prior to the formation of circuits on the exterior surfaces by drilling holes through the stack at appropriate locations. Following several pre-treatment steps, the walls of the holes are catalyzed by contact with a plating catalyst and metallized, typically by contact with an electroless or electrolytic copper plating solution to form conductive pathways between circuit layers. Following formation of the conductive thru-holes, exterior circuits, or outerlayers, are formed using the procedure described above.

The necessity of developing ever-increasing high speed circuitized substrates for use in many of today's new products has led to the exploration of new materials to extend the electrical and thermal performance limits of the presently available technology. For miniaturization of circuitized substrates, it is necessary to have extremely dense conductor circuitry patterning, and high-speed applications are enhanced by the use of low dielectric constant insulating material. Prepreg laminates for conventional circuit boards consist of a base reinforcing glass fabric impregnated with a resin, also referred to by some in the industry as FR-4 dielectric material. Epoxy/glass laminates used in some current products typically contain about 40% by weight fiberglass and 60% by weight epoxy resin.

The presence of fiberglass within the multilayered structure, especially woven fiberglass, also substantially impairs the ability to form high quality, very small thru-holes using laser drilling (ablation), one of the preferred means to form such thru-holes. Fiberglass cloth has drastically different absorption and heat of ablation properties than typical thermo-set or thermo-plastic matrix resins. In a typical woven glass cloth, for example, the density of glass a laser might encounter can vary from approximately zero percent in a window area to approximately fifty percent by volume or even more, especially in an area over a cloth knuckle. This wide variation in encountered glass density leads to problems obtaining the proper laser power for each thru-hole and may result in wide variations in thru-hole quality, obviously unacceptable by today's very demanding manufacturing standards.

The challenges for organic substrates in meeting these electrical requirements include using high-speed, low-loss materials, manufacturing precise structures, and making a reliable finished product. In addition, many high-speed chip packages have mechanical and environmental requirements such as lightweight and low moisture absorption. The LCP dielectric has a combination of features and performance that meet these requirements.

Currently, in the fabrication of substrates containing microelectronic circuits and LCP dielectric materials, adhesion at LCP to LCP and LCP to Cu interfaces is difficult to achieve. The disadvantages of melting LCP dielectric during lamination outweigh the advantages. LCP melting promotes surface wetting, interfacial interdiffusion, chemical bonding, and mechanical interlocking that all contribute to adhesion. More importantly, melting disrupts the crystallinity of the LCP dielectric and creates changes in the LCP thermo/mechanical properties that are undesirable. LCP melting also produces distortions of circuits already formed on LCP, reducing alignment accuracy and precision of the interconnections of vertically scaled multilayer circuits.

In semiconductor chip fabrication and packaging, the steps of etching different layers are among the more critical and crucial steps. Methods that are commonly used for the selective etching and chemical surface modification of organic polymers, including photoresists and dielectric substrates, include dry etching processes such as oxygen plasma etching and reactive ion etching in an oxygen containing plasma. These tools are utilized in the present invention to create a surface that has enhanced adhesion properties for both LCP to LCP and LCP to Cu bonding.

Oxygen plasma etching and chemical surface modification are procedures that generally involve filling a processing chamber with gas capable of providing chemically reactive oxygen atoms and ions. The substrate that is to be etched can be either blank or covered by a mask before being introduced into the chamber along with the reactive gas. The reactive gas is usually disassociated forming neutral atomic oxygen, and positive and negative ions by coupling radio frequency (RF) power to the plasma by a capacitive or inductive coupling. The disassociated atoms and ions then chemically react with the surface to be etched. In such a process, the substrates are positioned either on a ground plane, an RF powered plane, or an electrically floating surface (neither grounded or powered).

In reactive ion etching, generally a processing chamber is filled with a gas capable of providing chemically reactive oxygen atoms and ions. The cathode is negatively biased relative to the anode, for instance, by means of an applied radio frequency signal. The surface to be etched is either blank or covered by a suitable mask and is then placed on the cathode. By applying an electric field, the reactive gas disassociates and the chemically reactive oxygen gas ions are attracted to the cathode. The surface is etched both by chemical reaction with the active atoms and ions and by the momentum transfer of the ions impinging on the surface.

### DISCUSSION OF RELATED ART

U.S. Pat. No. 5,527,566 for CONDITIONING OF A POLYMERIC SUBSTRATE, issued Jun. 18, 1996 to Schadt, et al., discloses a polymeric substrate that is exposed to an oxygen containing plasma; and then exposed to a reducing atmosphere at an elevated temperature. The reducing treatment reverses the effects on the polymer surface chemistry by action of the oxidizing plasma. In this manner, the original electroactive properties of certain polymers are regenerated at the surface.

U.S. Pat. No. 5,703,202 for PROCESS FOR TREATING LIQUID CRYSTAL POLYMER FILM, issued Dec. 30, 1997 to Jester, et al., discloses a process for treating a liquid crystal polymer film which includes the steps of: heating a film obtained by extrusion molding of a liquid crystal polymer, while contacting at least one surface of the film with a supporting body, to melt the polymer; cooling the melted polymer to form a solidified polymer layer; and separating the solidified polymer layer from the supporting body. The process readily provides liquid crystal polymer films having excellent resistance to intra-layer delamination and high tensile strength and elongation, as well as excellent resistance to abrasion, dimensional stability when heated, and resistance to folding.

U.S. Pat. No. 5,679,414 for LIQUID CRYSTAL-POLYMER COMPOSITE FILM, ELECTRO-OPTICAL ELEMENT USING THE SAME, AND PROCESS FOR PRODUCING ELECTRO-OPTICAL ELEMENT, issued Oct. 21, 1997 to Akashi, et al., discloses a liquid crystal-polymer composite film comprising a high-molecular weight compound containing at least one kind of monomer unit. A side chain has a liquid crystal nature and at least one kind of monomer unit. A side chain has no liquid crystal nature. A low-molecular weight liquid crystal, the high-molecular weight compound and the low-molecular weight liquid crystal are in separate phases. The monomer units provide a side chain having no liquid crystal nature being crosslinked, and an electro-optical element comprising a pair of substrates each having an electrode. Interposed between them is a liquid crystal-polymer composite film comprising a low-molecular weight liquid crystal and a high-molecular weight compound in separate phases. The substrates each having a surface comprising a material having a reactive group on the side in contact with the composite film with the reactive group being chemically bonded to the high-molecular weight compound in the composite film.

U.S. Pat. No. 6,602,583 for LIQUID CRYSTALLINE POLYMER BOND PLIES AND CIRCUITS FORMED THEREFROM, issued Aug. 5, 2003 to St. Lawrence et al., discloses a multi-layer circuit board that comprises a liquid crystalline polymer bond ply disposed between two circuit layers. The liquid crystalline polymer bond ply is formed by treating a film comprised of q liquid crystalline polymer with an amount of heat and pressure applied to produce a liquid crystalline polymer bond ply, with an in-plane coefficient of thermal expansion (CTE) of 0 to about 50 ppm/° C. The multi-layer circuit is formed by lamination at a temperature of 0° C. to about 10° C. less than the melt temperature of the liquid crystalline polymer.

U.S. Pat. No. 6,696,163 for LIQUID CRYSTAL POLYMERS FOR FLEXIBLE CIRCUITS, issued Feb. 24, 2004 to Yang, discloses a process for providing a metal-seeded liquid crystal polymer. The steps for a liquid crystal polymer substrate to be treated begin by applying an aqueous solution comprising an alkali metal hydroxide and a solubilizer as an etchant composition for the liquid crystal polymer substrate. Further treatment of the etched liquid crystal polymer substrate involves depositing an adherent metal layer on the etched liquid crystal polymer substrate. An adherent metal layer may be deposited using either electroless metal plating or vacuum deposition of metal such as by sputtering. When using electroless metal plating, a tin(II) solution applied to the liquid crystal polymer provides a treated liquid crystal polymer substrate to which the application of a palladium(II) solution provides the metal-seeded liquid crystal polymer. The etchant composition comprises a solution in water of an alkali metal salt, and a solubilizer dissolved in the solution to provide the etchant composition suitable for etching the liquid crystal polymer.

U.S. Pat. No. 6,923,919 for LIQUID CRYSTAL POLYMERS FOR FLEXIBLE CIRCUITS, issued Aug. 2, 2005 to Yang, et al., discloses a process for providing a metal-seeded liquid crystal polymer. The steps for a liquid crystal polymer substrate to be treated begin by applying an aqueous solution comprising an alkali metal hydroxide and a solubilizer as an etchant composition for the liquid crystal polymer substrate. Further treatment of the etched liquid crystal polymer substrate involves depositing an adherent metal layer on the etched liquid crystal polymer substrate. An adherent metal layer may be deposited using either electroless metal plating or vacuum deposition of metal such as by sputtering. When using electroless metal plating, a tin(II) solution applied to the liquid crystal polymer provides a treated liquid crystal polymer substrate to which the application of a palladium(II) solution provides the metal-seeded liquid crystal polymer. The etchant composition comprises a solution in water of an alkali metal salt and a solubilizer dissolved in the solution to provide the etchant composition suitable for etching the liquid crystal polymer.

United States Publication No. 2006/0124228 for APPARATUS AND METHOD FOR MANUFACTURING COPPER CLAD LAMINATE WITH IMPROVED PEEL STRENGTH, published Jun. 15, 2006 to Lee, et al., describes an apparatus and method for manufacturing a copper clad laminate. The apparatus has a coating process for thinly coating the surface of a copper foil with a thermoplastic liquid crystal polymer solution and a solvent removal process for drying the coated liquid crystal polymer solution to remove the solvent of the coated solution. The apparatus also has a thermal pressing process for laminating and thermally pressing a thermoplastic liquid crystal polymer film onto the copper foil using heating rolls to make a copper clad laminate.

United States Publication No. 2006/0151106 for METHOD FOR PRODUCING LAMINATE, published Jul. 13, 2006 to Hiraishi, et al., describes a laminate that is produced from a film of a liquid crystal polymer. The laminate forms an optically anisotropic molten phase and a metal foil is bonded by thermo-compression bonding of a the two materials between pressing rolls. The method uses a metal roll coated with a resin such as fluororubber and polyimide as at least one of the pressing rolls. A heat-resistant film on the surface of a pile of polymer film and metal foil contacting a metal pressing roll and passing the resulting pile between metal pressing rolls may be used.

The previously disclosed United States issued patents and published patent application fail to adequately describe the present invention's LCP surface preparation techniques to enhance the interface adhesion of both metal to LCP and LCP to LCP.

It is therefore an object of the invention to provide an LCP surface modification operation that creates enhanced adhesion strength of metal and subsequent layers of LCP.

It is also an object of this invention to use oxygen plasma to alter the surface molecular layer of an LCP dielectric to create a surface more amenable to interfacial adhesion between metal and LCP.

It is also an object of this invention to utilize the alteration of the surface molecular layer for increased dimensional stability during lamination by incurring temperature and pressure regimes lower than the requisite melting for unmodified LCP layers.

### SUMMARY OF THE INVENTION

According to the present invention, there is provided a method and structure of modifying the surface properties of an LCP substrate to improve adhesion qualities of metal and/or a second LCP layer. Optionally, a substrate for use in a printed circuit board has a liquid crystal polymer buildup layer.

A first aspect of the invention is directed to enhancing the adhesion of metal to a surface layer of any LCP substrate.

A second aspect of the invention is directed to enhancing LCP to LCP surface layer adhesion during bonding.

A third aspect of the invention is directed to enhancing LCP surface adhesion without entering an LCP melt stage.

LCP materials have electrical properties compatible with transmission of signals at multi-GHz frequencies, including low moisture absorption and low electrical loss. These properties combine to make LCP a good material for use in electronic substrates. However, adhesion of laminates, whether metal or another layer of LCP, is difficult to achieve without entering the melt stage of the LCP.

### DESCRIPTION OF THE PREFERRED EMBODIMENT

In the invention, a method is provided for substrate surface modification for use in electronic packages in which a liquid crystal polymer (LCP) surface modification provides an increase in adhesion tendencies concomitant with a surface more amenable for metal plating.

For a better understanding of the present invention, together with other and further objects, advantages and capabilities thereof, reference is made to the following disclosure and appended claims.

By the term “circuitized substrate” as used herein is meant a substrate structure having at least one (and preferably more) dielectric layer and at least one external conductive layer positioned on the dielectric layer and including a plurality of conductor pads as part thereof. The dielectric layers referenced herein are generally made of LCP material as the adhesion strength of copper to other dielectric types is well known and not part of this description. The conductive layers preferably serve to conduct electrical signals, including those of the high frequency type, and is preferably comprised of suitable metals such as copper, chromium, and titanium.

By the term “electroplating” as used herein is meant a process by which a metal in its ionic form is supplied with electrons to form a non-ionic coating on a desired substrate. The most common system involves: a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal.

By the term “electroless plating” (also known as chemical or auto-catalytic plating) as used herein is meant a non-galvanic type of plating method that involves several simultaneous reactions in an aqueous solution, which occur without the use of external electrical power. The reaction is accomplished when hydrogen is released by a reducing agent, normally sodium hypophosphite, and oxidized thus producing a negative charge on the surface of the part.

By the term “electronic package” as used herein is meant a circuitized substrate assembly as taught herein having one or more ICs (e.g., semiconductor chips) positioned thereon and electrically coupled thereto. In a multi-chip electronic package, for example, a processor, a memory device and a logic chip may be utilized and oriented in a manner designed for minimizing the limitation of system operational speed caused by long connection paths. Some examples of such packages, including those with a single chip or a plurality thereof, are also referred to in the art as chip carriers.

By the term “etch” and “etching” as used herein is meant a process by where a surface of a substrate is either selectively etched using a photoresist or covered by a mask prior to plasma treating, both methods are meant to transfer an image onto the substrate for subsequent further processing, or for chemical surface modification of the actual LCP surface and trace contaminant residuals remaining on the surface from the LCP manufacturing process or purposely placed on the surface.

By the term “laser ablation” as used herein is meant the process of removing material from a solid surface by irradiating it with a laser beam. At low laser flux, the material is heated by the absorbed laser energy and evaporates or sublimes. At high laser flux, the material is typically converted to a plasma. The term laser ablation as used herein refers to removing material with a pulsed laser as well as ablating material with a continuous wave laser beam if the laser intensity is high enough.

By the term “thru-hole” as used herein is meant to include what are also commonly referred to in the industry as blind vias which are openings typically from one surface of a substrate to a predetermined distance therein, internal vias which are vias or openings located internally of the substrate and are typically formed within one or more internal layers prior to lamination thereof to other layers to form the ultimate structure, and plated thru-holes (PTHs), which typically extend through the entire thickness of a substrate. All of these various openings form electrical paths through the substrate and often include one or more conductive layers, e.g., plated copper, thereon. Alternatively, such openings may simply include a quantity of conductive paste or, still further, the paste can be additional to plated metal on the opening sidewalls. These openings in the substrate are formed typically using mechanical drilling or laser ablation, following which the plating and/or conductive paste may be added.

Other definitions are readily ascertainable from the detailed descriptions provided herein.

To increase the chemical component of adhesion while avoiding problems associated with LCP melting described hereinabove, an oxygen plasma treatment can enhance the chemical component of adhesion, allowing strong interfacial chemical bonding in the absence of melt-driven interfacial bonding. This modification likely involves not only the plasma surface modification of the LCP polymer but some types of LCP films (for example, Rogers Corp. ULTRALAM 3000 LCPs) have silicon-containing materials present as residuals from an original manufacturing-processing step. Thus, the overall adhesion enhancement is due to the simultaneous modification of both the LCP polymer and these surface impurities. It is known that transformation of O—Si—C compounds as detected on some LCP films, via oxygen plasma, leads to the formation of SiOₓ surfaces with some levels of hydroxylation. Thus the overall chemical interaction between two modified surfaces uses these two different surface modifications to yield increased adhesion properties.

It has also been shown, using X-ray photoelectron spectroscopy (XPS) that other contaminants, such as fluorine, nitrogen, and trace amounts of reactants and diluents have residues that remain in the plasma chamber after use. The residues remaining in the plasma chamber can be incorporated into the LCP surface during plasma treatment and detected using XPS. If the residues and contaminants are in low concentrations, they will not affect the interfacial strength between the surface-modified layers.

A type of useful LCP for these applications has the structure shown below:

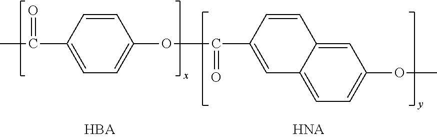

wherein HBA is p-Hydroxybenzoic acid and HNA is 6-Hydroxy-2-naphthoic acid. Estimated values for x and y are 73% and 27%, respectively.

Applicants' use of vacuum based plasma systems, such as reactive ion etch (RIE) and roll-to-roll plasma system, utilize plasma of pure oxygen (O₂) to etch and modify the LCP and any impurities thereon. The plasma process modifies the surface components that contain C—Si—O bonds. These components are either purposely incorporated into LCP films during manufacture or come from the manufacturing methods used to create the film, such as a mold release compound. Certain impurities may also be purposefully introduced during the plasma stage to act as a marker for the process. Treatments such as oxygen plasma in static or dynamic modes transform the C—Si—O groups to Si—OH groups. These groups are compatible with oxidized polymer surface segments, thus yielding a strong interface to subsequent manufacturing processes, such as lamination and metal adhesion. Using the processes described herein has produced peel force measurement results that are 20× higher than similar untreated test samples.

In accordance with the present invention, the steps involved with surface treatment of LCP include the entire surface being treated, or portions of the LCP surface being imagewise selectively exposed to a dry etching procedure employing an oxygen containing atmosphere. In particular, oxygen plasma and oxygen RIE techniques can be used. In an oxygen plasma treatment, a power range of from about 100 to about 400 watts and preferably 300 watts can be employed. The treatment is performed for approximately 2 to 10 minutes with 2 minutes being the preferable time, as the adhesion properties are highest at this point and begin to decline after this.

The chamber for carrying out the treatment normally contains oxygen to a pressure of about 1 torr and preferably about 1-3 torr. The gas employed is usually ultrapure and the preferred flow rate of the gas employed is approximately 100 standard cubic centimeters per minute (SCCM).

In an oxygen containing RIE technique, the LCP substrate to be etched is placed on a cathode plate connected to a cathode that is typically a radio frequency electrode. Also included in such a configuration is an anode and a power source, such as AC and preferably a radio frequency power source.

The RIE is generally carried out under vacuum at pressures preferably about 5 to about 500 millitorr in batch processing systems. A convenient power density for operating the radio frequency power source is <0.5 and preferably about 0.2 to about 0.4 watts per cm² of the cathode for batch systems. The flow rate of the oxygen is generally at least about 10 SCCM, with a preferred flow rate being about 10 to about 30 SCCM.

Since other modifications to the liquid crystal polymer surface adhesion effected as such will be apparent to those skilled in the art, the invention is not considered limited to the description above for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A method of conditioning a liquid crystal polymer (LCP) substrate for enhanced surface adhesion, comprising:
exposing an LCP substrate to an oxygen plasma; and
modifying said LCP substrate surface in said oxygen plasma.

2. The method of claim 1, wherein said oxygen plasma contains ultrapure oxygen provided at a pressure of more than 1 torr.

3. The method of claim 2 wherein said pressure is from about 1 to about 3 torr.

4. The method of claim 1, wherein the exposure to said plasma is sustained for approximately 2 to approximately 10 minutes.

5. The method of claim 1, further comprising incorporating impurities residing on said substrate surface and in a plasma chamber into the surface of said LCP substrate.

6. The method of claim 5, wherein said impurities originate from at least one of the group: manufacturing residuals, plasma chamber residuals, and purposely introduced impurities.

7. The method of claim 1, wherein at least one region of said LCP substrate is imagewise selectively exposed to plasma.

8. The method of claim 1, further comprising contacting said at least one modified LCP substrate surface region to deposit an electrically conductive metal thereon with a process selected from the group: sputter deposition, electroplating, and electroless-plating.

9. The method of claim 8, wherein said electrically conductive metal is selected from the group: copper, chromium, and titanium.

10. The method of claim 1, wherein said LCP substrate is blanket exposed to said oxygen containing plasma.

11. A method of conditioning a liquid crystal polymer (LCP) substrate for enhanced surface adhesion, comprising:
exposing an LCP substrate to a reactive ion etch (RIE) oxygen plasma; and
modifying said LCP substrate surface in said RIE oxygen plasma.

12. The method of claim 11, wherein said oxygen plasma contains ultrapure oxygen provided at a pressure of more than 1 millitorr.

13. The method of claim 12 wherein said pressure is from about 5 to approximately 500 millitorr.

14. The method of claim 11, wherein the exposure to said RIE plasma is sustained for approximately 10 to approximately 35 seconds.

15. The method of claim 11, wherein regions of said LCP substrate less than the entire substrate are imagewise selectively exposed to RIE plasma.

16. The method of claim 11, further comprising contacting said at least one modified LCP substrate surface region to deposit an electrically conductive metal thereon with a process selected from the group: sputter deposition, electroplating, and electroless-plating.

17. The method of claim 16, wherein said electrically conductive metal is selected from the group: copper, chromium, and titanium.

18. The method of claim 11, wherein said LCP substrate is blanket exposed to said oxygen containing RIE plasma.

19. The method of claim 11, further comprising incorporating impurities residing in an RIE plasma chamber into a surface of said LCP substrate.

20. The method of claim 19, wherein said impurities originate from at least one of the group: manufacturing residuals, RIE plasma chamber residuals, and purposely introduced impurities.

21. An LCP substrate comprising at least one plasma-modified surface region having a plurality of impurities contained therein.

22. The LCP substrate of claim 21, wherein said plurality of impurities comprises at least one of the group: Fluorine, Si—O, Xenon, and Krypton.

23. A method of detecting impurities after conditioning a liquid crystal polymer (LCP) substrate for enhanced surface adhesion, comprising:
a) providing an LCP substrate exposed to an oxygen plasma; and
b) detecting impurities upon said LCP substrate surface.

24. The method of claim 23, wherein said detecting said impurities comprises at least one tool from the group: X-ray photoelectron spectroscopy (XPS) and photoemission spectroscopy (PES).
